(19) United States
(12) Patent Application Publication
(10) Pub. No.: US 2008/0085008 A1
(43) Pub. Date: Apr. 10, 2008

(54) Frequency Domain Reverberation Method and Device

(76) Inventor: Earl Corban Vickers, Saratoga, CA (US)

Correspondence Address: Earl C. Vickers, 12510 Paseo Cerro, Saratoga, CA, 95070, US

(21) Appl. No.: 11/864,975

(22) Filed: Sep. 29, 2007

Related U.S. Application Data
(60) Provisional application No. 60/849,634, filed on Oct. 4, 2006.

(51) Int. Cl. H03G 3/00

(52) U.S. Cl. 381/63

(57) ABSTRACT

A method and device for creating late reverberation in the frequency domain using spectral magnitude decay. The method applies a frequency domain representation of an input signal to a frequency domain accumulator having a delay, an adder and a frequency-dependent magnitude attenuation. The attenuated magnitude is combined with an artificial phase signal to produce one or more output signals. The method enables detailed control of late reverberation decay times as a function of frequency.

### CROSS REFERENCE TO RELATED APPLICATIONS

This application claims the benefit of provisional patent application Ser. No. 60/849,634, filed Oct. 4, 2006.

### BACKGROUND OF THE INVENTION

1. Field of the Invention

The present invention relates to artificial audio reverberation, and more specifically to a method and device for creating artifical audio late reverberation in the frequency domain using spectral magnitude decay.

Reverberation refers to the reflections produced when a sound travels from a source to a listener by bouncing off a number of different surfaces. Reverberation helps our brains determine what kind of environment we're in. Artifical reverberation devices, known as reverbs, are used for processing music and voice, as well as for simulating various rooms and other environments for interactive games.

Late reverberation refers to the diffuse portion of a room's impulse response (typically starting around 100 ms.), characterized by a very large number of echoes and an intensity that is relatively independent of the position within the room. Late reverberation lends itself to a statistical description.

2. Description of Prior Art

There are many existing methods for generating artificial late reverberation.

Time domain reverb algorithms, such as feedback delay networks, typically require a great deal of delay line memory, often one or two seconds or more. Depending on the processor, this delay line memory often requires external memory accesses, which may be scarce.

While the reverb decay envelope of a time domain reverb can be made frequency dependent in order to better simulate a particular acoustical environment, typically only two or three bands of decay time control are provided, due to the expense of placing multi-band equalizers in each feedback path.

Convolution reverbs are typically implemented in the frequency domain for reasons of efficiency. While convolution can produce an excellent simulation of the acoustics of a particular space, it does not offer flexible parametric control over the decay spectra. Furthermore, the computational cost increases as a function of the decay time.

### REFERENCES TO PRIOR ART

W. Gardner, “Reverberation Algorithms,” in Applications of Digital Signal Processing to Audio and Acoustics, Kluwer Academic Publishers, Norwell, Md., 1998.

J.-M. Jot and A. Chaigne, “Digital delay networks for designing artificial reverberators,” Proc. 90th Conv. Audio Eng. Soc. (preprint no. 3030), 1991.

J. Laroche and M. Dolson, “Phase-Vocoder: About this phasiness business,” Proc. IEEE Workshop on Applications of Signal Processing to Audio and Acoustics, New Paltz, N.Y., 1997.

J. Moorer, “About this reverberation business,” Computer Music Journal, 3(2):13-28, 1979.

J. Flanagan and R. Golden, “Phase vocoder,” Bell Syst. Tech. J., vol. 45, pp. 1493-1509, November 1966.

D. Griffin and J. Lim, “Signal estimation from modified short-time fourier transform,” IEEE Trans. Acoust., Speech, Signal Processing, vol. ASSP-32, no. 2, pp. 236-243, April 1984.

M. Dolson, “The phase vocoder: A tutorial,” Computer Music Journal, vol. 10, pp. 14-27, 1986.

D. Arfib, F. Keiler, U. Zölzer, “Time-frequency Processing,” DAFX—Digital Audio Effects, John Wiley & Sons, Ltd., England, 2002.

A. De Götzen, N. Bernardini, D. Arfib, “Traditional (?) Implementations of a Phase-Vocoder: The Tricks of the Trade,” Proceedings of the COST G-6 Conference on Digital Audio Effects (DAFX-00), Verona, Italy, Dec. 7-9, 2000.

J. Laroche and M. Dolson, “Improved Phase Vocoder Time-Scale Modification of Audio,” IEEE Transactions on Speech and Audio Processing, Vol. 7, No. 3, May 1999.

J. Laroche, “Time and pitch scale modification of audio signals,” in Applications of Digital Signal Processing to Audio and Acoustics, Kluwer Academic Publishers, Norwell, Md., 1998.

M. Puckette, “Phase-locked Vocoder,” IEEE ASSP Conference on Applications of Signal Processing to Audio and Acoustics, Mohonk 1995.

R. Sussman and J. Laroche, “Application of the Phase Vocoder to Pitch-Preserving Synchronization of an Audio Stream to an External Clock,” Proc. 1999 IEEE Workshop on Applications of Signal Processing to Audio and Acoustics, New Paltz, N.Y., Oct. 17-20, 1999.

D. Dorran, E. Coyle, R. Lawlor, “An Efficient Phasiness Reduction Technique for Moderate Audio Time-Scale Modification,” Proceedings of the 7^{th} International Conference on Digital Audio Effects (DAFX '04), Naples, Italy, Oct. 5-8, 2004.

J. Brown and M. Puckette, “A high resolution fundamental frequency determination based on phase changes of the Fourier transform,” J. Acoust. Soc. Am., 94(2) :662-667, 1993.

M. Macon and M. Clements, “Sinusoidal Modeling and Modification of Unvoiced Speech,” IEEE Transactions on Speech and Audio Processing, pp. 557-560, November 1997.

E. Vickers, J. Wu, P. Krishnan, R. Sadanandam, “Frequency Domain Artificial Reverberation using Spectral Magnitude Decay,” Proceedings of the AES 121st Convention, Preprint 6926, Audio Engineering Society, San Francisco, Calif.

### SUMMARY OF THE INVENTION

The present invention relates to a method and device for creating artifical audio late reverberation in the frequency domain using spectral magnitude decay. The invention involves converting a time domain signal into the frequency domain (if it is not already in the frequency domain); applying frequency-dependent gains to the spectral magnitudes inside one or more feedback paths in order to implement a frequency-dependent decay time; creating an artificial phase signal; combining the magnitude and phase signals to create a frequency domain output; and converting the frequency domain output into a time domain signal.

One advantage of the invention is that it uses a relatively small amount of memory and, depending on the processor used, may not require any external memory accesses.

Another advantage of the invention is that, unlike existing time domain reverbs, the invention can easily provide independent control over the reverb energy and decay time in each of hundreds or thousands of frequency channels.

Another advantage of the invention is that, unlike convolution, the invention provides flexible parametric control over the reverb decay spectra.

Another advantage of the invention is that, unlike existing convolution reverbs, the preferred embodiment of the invention has a computational cost which is independent of the decay time.

Another advantage of the invention is that, unlike previous reverbs, the invention facilitates a novel form of cross-synthesis in which the spectral magnitude of one signal can be used to control the reverberant decay time applied to another signal.

Another advantage of the invention is that it will prove especially efficient and useful for systems in which the audio has already been transformed into the frequency domain for other types of processing.

### DESCRIPTION OF THE DRAWINGS

The present invention may be better understood, and its numerous features and advantages made apparent to those skilled in the art, by referencing the accompanying drawings.

FIG. 1 is a block diagram of the short-time Fourier Transform, STFT, (prior art).

FIG. 2 is a block diagram of a modified comb filter with frequency-dependent feedback gain (prior art).

FIG. 3 is a simplified block diagram of the preferred embodiment of the invention, with frequency-dependent feedback gain.

FIG. 4 is a smooth quasi-exponential decay produced by overlap-adding scaled Hanning windows.

FIG. 5A is an impulse response of the Spectral Magnitude Decay method.

FIG. 5B is an Energy Decay Curve (EDR) in dB, derived from the impulse response in FIG. 5A.

FIG. 6 is a block diagram of phase computation based on a continuation of the instantaneous frequency.

FIG. 7 is a detailed block diagram of the preferred embodiment of the invention, including phase randomization, room level as a function of frequency, and dry mix.

FIG. 8 is a block diagram of a time freeze algorithm (prior art).

FIG. 9 is a conceptual overview of an alternate embodiment of the invention using parallel time-freeze effects.

FIG. 10 is the impulse response of the parallel time-freeze in FIG. 9.

### DETAILED DESCRIPTION OF THE INVENTION

The following is a detailed description of illustrative embodiments of the present invention. As these embodiments of the present invention are described with reference to the aforementioned drawings, various modifications or adaptations of the methods and/or specific structures described may become apparent to those skilled in the art. All such modifications, adaptations, or variations that rely upon the teachings of the present invention, and through which these teachings have advanced the art, are considered to be within the spirit and scope of the present invention. Hence, these descriptions and drawings are not to be considered in a limiting sense, as it is understood that the present invention is in no way limited to the embodiments illustrated.

The present invention provides a system and method for producing artificial late reverberation in the frequency domain using spectral magnitude decay.

Our algorithm, performed in the short-time Fourier transform (STFT) domain, attenuates and accumulates the spectral magnitudes, which are combined with a computed phase signal. This method yields an impulse response with a smooth, exponentially decaying envelope and independent control over room energy and decay time at each frequency.

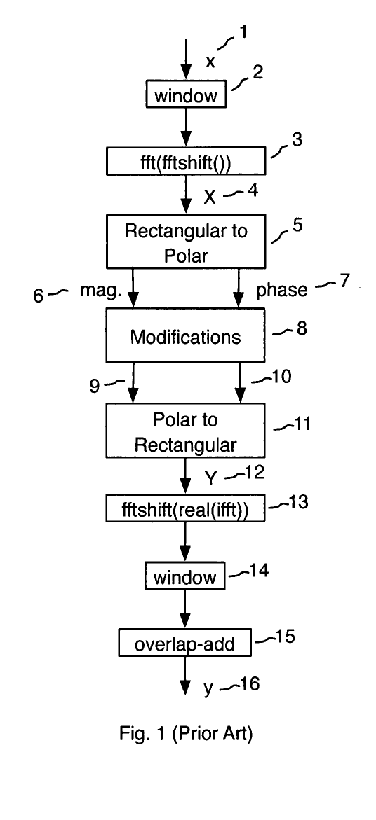

Given that we wish to extend the temporal evolution of a signal while retaining independent control over its spectral content, our basic tool is the STFT, which allows a signal to be analyzed into a time-frequency grid, optionally modified in various ways, and resynthesized, as shown in FIG. 1.

The phase vocoder can be efficiently implemented using the STFT. A common application of the phase vocoder is to implement time-scaling while preserving the pitch and spectra. To review, this is done as follows:

1. Compute the STFT of the input signal.

$$X ( {t}_{a}^{u} , {Ω}_{k} ) = {\sum }_{n = - ∞}^{∞} h ( n ) x ( {t}_{a}^{u} + n ) {e}^{- {jΩ}_{k} n} ,$$

where x is the input signal, X is the input's STFT representation, h(n) is the analysis window,

$${Ω}_{k} = \frac{2 π k}{N}$$

is the center frequency of the k^{th} vocoder channel (or bin), N is the size of the discrete Fourier transform, Rₐ is the analysis hop size in samples, u is a set of successive integers starting at 0, and tₐ^{u}=uRₐ is the time of the u^{th} analysis frame.

2. For each channel k and analysis time-instant tₐ^{u},
(a) Obtain the phase Øₖ(tₐ^{u})=∠X(tₐ^{u},Ωₖ),
(b) Calculate the heterodyned phase increment

$${ΔΦ}_{k}^{u} = {φ}_{k} ( {t}_{a}^{u} ) - {φ}_{k} ( {t}_{a}^{u - 1} ) - {R}_{a} {Ω}_{k}$$

(c) Take its principal determination (between ±π), denoted by ΔₚΦₖ^{u}, which can be regarded as the amount of frequency deviation from Ωₖ,
(d) Estimate the instantaneous frequency,

$${\hat{ω}}_{k} ( {t}_{a}^{u} ) = {Ω}_{k} + \frac{1}{{R}_{a}} {Δ}_{p} {Φ}_{k}^{u} ,$$

(e) Set the phase of the time-stretched STFT at synthesis time tₛ^{u}=Rₛu , where Rₛ is the synthesis hop size, according to the phase-propagation formula,

$$∠Y ( {t}_{s}^{u} , {Ω}_{k} ) = ∠Y ( {t}_{s}^{u - 1} , {Ω}_{k} ) + {R}_{s} {\hat{ω}}_{k} ( {t}_{a}^{u} ) ,$$

(f) Set the magnitude |Y(tₛ^{u},Ωₖ)|=|X(tₐ^{u},Ωₖ)|,
(g) Obtain the output signal by overlap-adding the IDFTs of the synthesis frames Y(tₛ^{u},Ωₖ), as follows:

$$y ( n ) = {\sum }_{u = - ∞}^{∞} w ( n - {t}_{s}^{u} ) {y}_{u} ( n - {t}_{s}^{u} ) , \\ where$$

$${y}_{u} ( n ) = \frac{1}{N} {\sum }_{k = 0}^{N - 1} Y ( {t}_{s}^{u} , {Ω}_{k} ) {e}^{{jΩ}_{k} n}$$

FIG. 1 is a block diagram of the short-time Fourier Transform, STFT, (Prior Art). At each hop time (or frame), the input signal x 1 is windowed by a Hanning or similar window 2. A left-right-swapper-and-fast-Fourier-transform (similar to Matlab functions fft(fftshift( ))) 3 converts the windowed input signal into the frequency domain, resulting in STFT signal 4,

$$X ( {t}_{u} , {Ω}_{k} ) = {\sum }_{n = - ∞}^{∞} h ( n ) x ( {t}_{u} + n ) {e}^{- {jΩ}_{k} n} .$$

The STFT signal 4 is converted to polar coordinates in Rectangular-to-Polar Converter 5, yielding magnitude 6 and phase 7. Magnitude 6 and Phase 7 may be modified by Modifications 8, resulting in modified magnitude 9 and modified phase 10. Modified magnitude 9 and modified phase 10 are converted to rectangular coordinates in Polar-to-Rectangular Converter 11 to produce the Fourier transform signal Y 12. The Fourier transform signal Y 12 is converted back to the time domain by an inverse-Fourier-transform-and-left-right swapper (similar to Matlab fftshift(real(ifft( )))) 13. The resulting time domain signal is windowed by a Hanning or similar window 14 and overlap-added in overlap-adder 15 to produce output y 16.

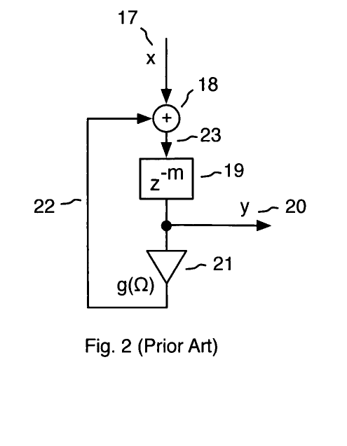

FIG. 2 (Prior Art) is a block diagram of Moorer's improved comb filter, which had a frequency-dependent gain in the feedback loop and was a precursor of the feedback delay network (FDN) reverberator. The input signal x 17 is added to feedback signal 22 in adder 18 to produce a sum signal 23 which is delayed by m samples in delay 19 to produce output signal y 20. Output signal y 20 is multiplied by a frequency-dependent gain g(Ω) 21 to produce feedback signal 22.

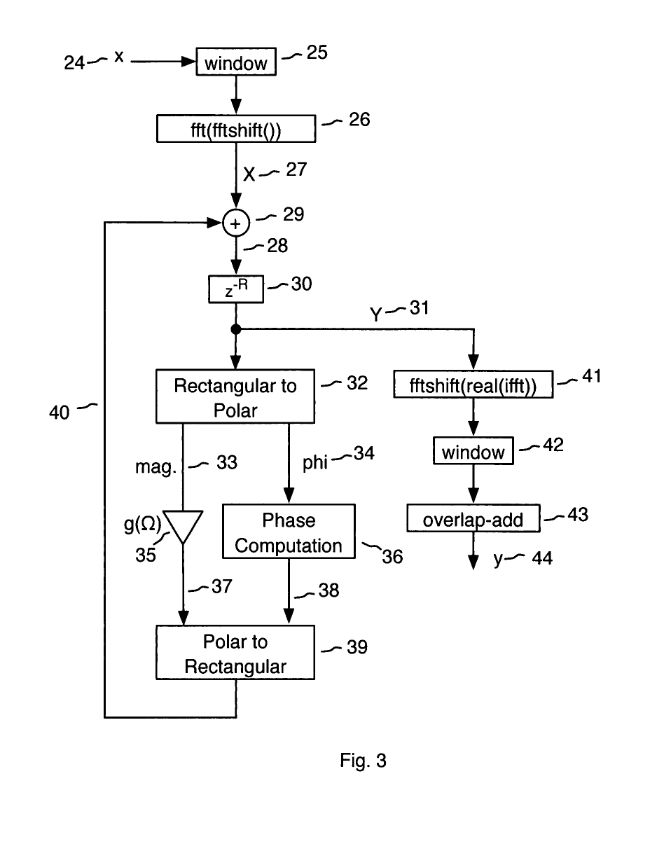

A simplified block diagram of the preferred embodiment of the invention is shown in FIG. 3. This method can be viewed as loosely analogous, in the frequency domain, to Moorer's improved comb filter, in that both methods involve a frequency-dependent gain inside a feedback loop.

At each hop time (or frame), the input signal x 24 is windowed by a Hanning or similar window 25. A left-right-swapper-and-fast-Fourier-transform (similar to Matlab functions fft(fftshift( ))) 26 converts the windowed input signal into the frequency domain, resulting in STFT signal 27,

$$X ( {t}_{u} , {Ω}_{k} ) = {\sum }_{n = - ∞}^{∞} h ( n ) x ( {t}_{u} + n ) {e}^{- {jΩ}_{k} n} .$$

The STFT signal 27 is added to a feedback Fourier transform 40 in adder 29; the sum 28 is delayed by one frame (R samples) in delay 30, yielding the delayed sum Fourier transform signal Y(tᵤ,Ωₖ) 31, which is converted to polar coordinates in Rectangular-to-Polar Converter 32, yielding magnitude 33 and phase 34. Magnitude 33 is attenuated as a function of the desired frequency-dependent decay time by gain g(Ω) 35, resulting in attenuated magnitude 37. The phase signal 34 feeds into Phase Computation 36, yielding artificial phase signal 38. The attenuated magnitude 37 is combined with artificial phase signal 38 and converted to rectangular coordinates in Polar-to-Rectangular Converter 39 to produce the feedback Fourier transform signal 40.

The delayed sum Fourier transform signal Y(tᵤ,Ωₖ) 31 is converted back to the time domain by an inverse-Fourier-transform-and-left-right swapper (similar to Matlab fftshift(real(ifft( )))) 41. The resulting time domain signal is windowed by a Hanning or similar window 42 and overlap-added in overlap-adder 43 to produce output y 44.

At each frame, the accumulated magnitude in each frequency bin is given by the equation

|Y(tᵤ,Ωₖ)|=|X(tᵤ₋₁,Ωₖ)|+|Y(tᵤ₋₁,Ωₖ)|·g(Ωₖ)

To determine the g(Ωₖ) attenuation values, we begin by specifying the desired Tᵣ(Ωₖ), the reverberation time (in seconds) required for the sound pressure to decay 60 dB at each frequency Ωₖ. Assuming the decay rate is linear in dB, the rate at which the sound pressure decays during one STFT hop should equal the rate implied by Tᵣ(Ωₖ), as follows:

$$\frac{20 {log}_{10} ( g ( {Ω}_{k} ) )}{R / {f}_{s}} = \frac{- 60}{{T}_{r} ( {Ω}_{k} )} .$$

Therefore, the attenuation for the k^{th} bin is given by

$$g ( {Ω}_{k} ) = {10}^{\frac{3 R}{{T}_{r} ( {Ω}_{k} ) {f}_{s}}} .$$

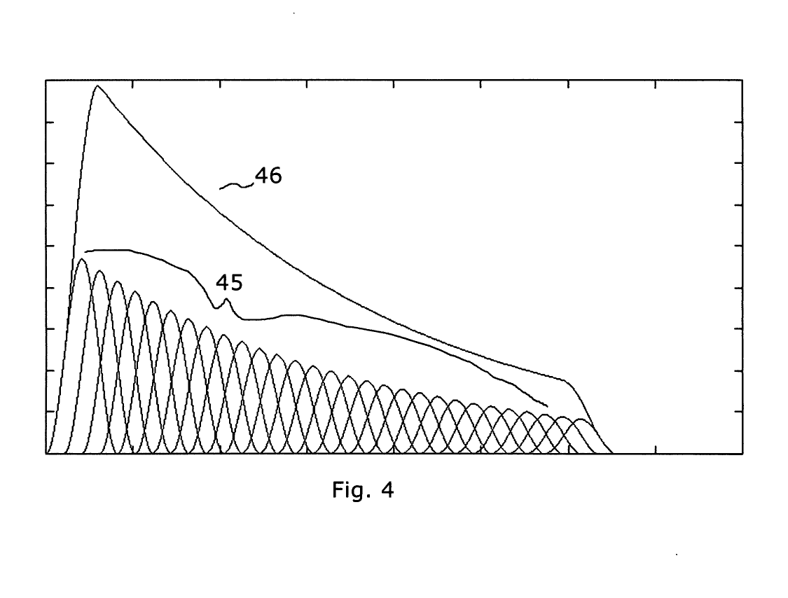

If we want the reverb's impulse response to have an exponential decay, the individual windowed STFT frames should overlap-add to produce a smoothly decaying exponential. FIG. 4 demonstrates that summing a series of overlapping Hanning windows 45, given sufficient overlap, and applying an additional gain factor of g to each successive window, yields a close approximation 46 of an exponential decay.

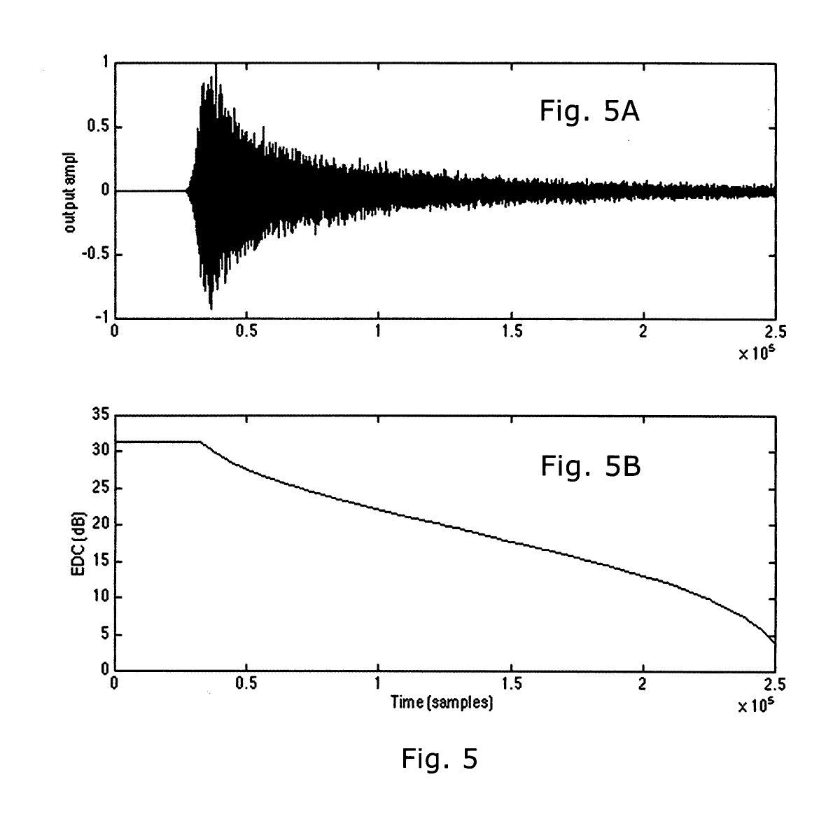

FIG. 5A illustrates a typical impulse response produced by feeding an impulse to the Spectral Magnitude Decay algorithm depicted in FIG. 3, where phase randomization has been used for all or part of Phase Computation 36.

An Energy Decay Curve (EDC) can be obtained by integrating the energy remaining in the impulse response after time t:

$$E D C ( t ) = {\int }_{t}^{∞} {h}^{2} ( τ ) d τ ,$$

where h(t) is the room's impulse response. FIG. 5B illustrate the EDC corresponding to the impulse response shown in FIG. 5A. It can be seen that the EDC is approximately linear in dB, as desired. A 3D Energy Decay Relief (EDR) of the Spectral Magnitude Decay's impulse response would reveal different decay rates at different frequencies, due to the frequency-dependent feedback gains.

The invention requires the generation of an artificial phase signal to be combined with the accumulated magnitude response. There are many possible ways of generating the phase signal. We will begin with a deterministic phase propagation method.

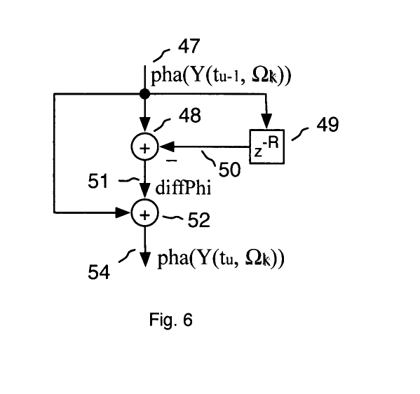

FIG. 6 is a block diagram showing a deterministic method of computing the phase by propagating the instantaneous frequencies of phase signal 34 from FIG. 3. In FIG. 6, phase signal 47 is delayed by 1 hop (R samples) in delay 49, resulting in delayed phase signal 50. Delayed phase signal 50 is negated and added to phase signal 47 in adder 48, resulting in difference phase signal diffPhi 51. Phase signal 47 is added to difference phase signal diffPhi 51 in adder 52, resulting in artificial phase signal 54.

If needed, a more accurate instantaneous frequency can be obtained by using a 1-sample delay time, z⁻¹, in delay 49.

When using the deterministic phase propagation method of FIG. 6 in Phase Computation 36 of the Spectral Magnitude Decay method of FIG. 3, the impulse response is extremely sparse and periodic with period N. The resemblance of room responses to decaying white noise and the natural occurrence of phase randomization in reverberant environments suggest that we should consider partially or totally randomizing the phases.

The phases of each frequency channel k can be modified at each frame by adding a random offset as follows: Øₖ^{s}(tᵤ)=Øₖ(tᵤ)+V_{k,u}ψ_{k,u}, where Øₖ(tᵤ) is the instantaneous phase of the k^{th} frequency channel at time tᵤ, Øₖ^{s}(tᵤ) is the instantaneous synthesis (output) phase of the k^{th} frequency channel at time tᵤ, ψ_{k,u} is a uniform random variable over [−π, π], and V_{k,u} ε[0,1].

Thus, when V_{k,u}=0 for all frequency channels k and all times tᵤ, no phase randomization is applied. If V_{k,u}=1, the phase offsets will be completely random.

Ideally, we would like to preserve and reverberate the instantaneous frequency information provided by diffPhi 51 in FIG. 6, while adding a controlled amount of phase randomization. By controlling V_{k,u}, we have a great deal of freedom regarding which channels undergo phase randomization, how frequently, and to what degree. As V_{k,u} increases from 0 to 1, the resulting random modulation disrupts the long-term periodicities, increasing the effective bandwidth of each sinusoidal component.

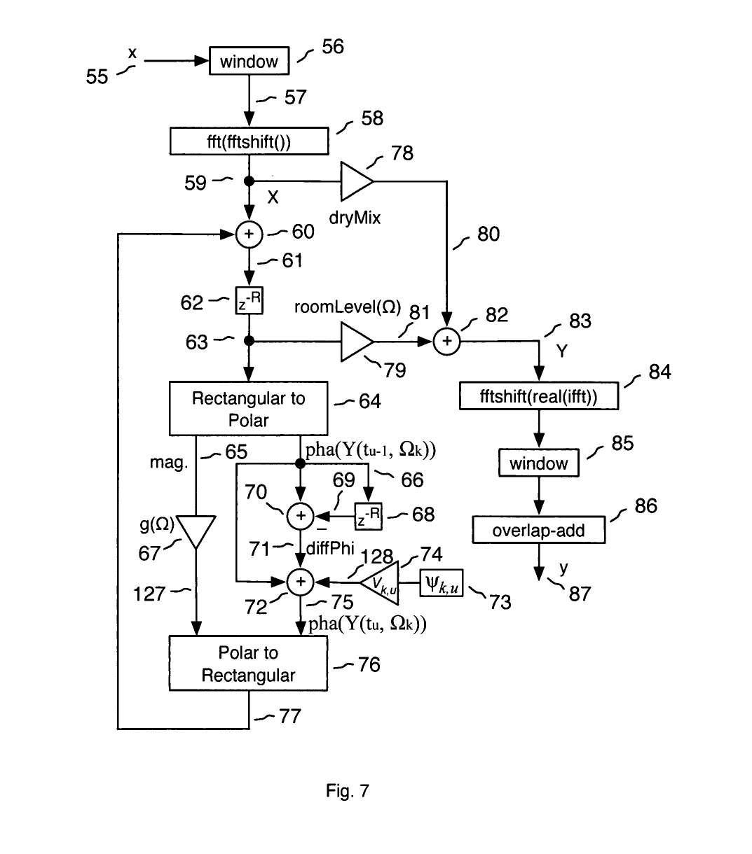

FIG. 7 is a block diagram of the detailed Spectral Magnitude Decay algorithm, including controlled phase randomization. At each hop time (or frame), the input signal x 55 is windowed by a Hanning or similar window 56, resulting in windowed input signal 57. A left-right-swapper-and-fast-Fourier-transform (similar to Matlab functions fft(fftshift( ))) 58 converts the windowed input signal 57 into the frequency domain, resulting in STFT signal 59,

$$X ( {t}_{u} , {Ω}_{k} ) = {\sum }_{n = - ∞}^{∞} h ( n ) x ( {t}_{u} + n ) {e}^{- {jΩ}_{k} n} .$$

The STFT signal 59 is added to a feedback Fourier transform 77 in adder 60, resulting in sum 61; the sum 61 is delayed by one frame (R samples) in delay 62, yielding the delayed sum Fourier transform signal Y(tᵤ,Ωₖ) 63, which is converted to polar coordinates in Rectangular-to-Polar Converter 64, yielding magnitude 65 and phase 66. Magnitude 65 is attenuated as a function of the desired frequency-dependent decay time by gain g(Ω) 67, where

$$g ( {Ω}_{k} ) = {10}^{\frac{3 R}{{T}_{r} ( {Ω}_{k} ) {f}_{s}}} ,$$

resulting in attenuated magnitude 127.

The phase signal 66 is delayed by 1 hop (R samples) in delay 68, resulting in delayed signal 69. Delayed signal 69 is negated and added to phase signal 66 in adder 70, resulting in difference phase signal diffPhi 71.

ψ_{k,u} 73 is a uniform random variable over [−π, π]. It is scaled by V_{k,u} 74, a gain between 0 and 1, to produce random phase signal V_{k,u}ψ_{k,u} 128.

Phase signal 66 is added to difference phase signal diffPhi 71 and random phase signal V_{k,u}ψ_{k,u} 128 in adder 72, resulting in artificial phase signal 75.

The attenuated magnitude 127 is combined with artificial phase signal 75 and converted to rectangular coordinates in Polar-to-Rectangular Converter 76 to produce the feedback Fourier transform signal 77.

The delayed sum Fourier transform signal Y(tᵤ,Ωₖ ) 63 is scaled by roomLevel(Ω) in multiplier 79, resulting in a scaled signal 81. STFT signal X 59 is scaled by dryMix gain 78, resulting in scaled signal 80. Scaled signal 81 is added to scaled signal 80 in adder 82, resulting in sum signal Y 83. Sum signal Y 83 is converted back to the time domain by an inverse-Fourier-transform-and-left-right swapper (similar to Matlab fftshift(real(ifft( )))) 84. The resulting time domain signal is windowed by a Hanning or similar window 85 and overlap-added in overlap-adder 86 to produce output y 87.

Phase randomization can be applied either inside or after the feedback loop. Applying randomization inside the loop, as shown in FIG. 7, may diffuse the impulse response more efficiently, using a smaller amount of randomization, than if we dither the phases outside the loop.

The following Matlab code implements a frequency domain Spectral Magnitude Decay reverb similar to that shown in FIG. 7:

| N | = 8192; |
|---|---|
| hop | = N/4; % Hop size (samples) |
| % Analysis & synthesis windows | |
| win | = .5*(1 − cos(2*pi*(0:N−1)’/(N))); |

| [x, FS] = wavread(‘SuzanneMono.wav’); | |
|---|---|
| x = [x; zeros(FS * 6, 1)]; | % Add some silence to let the |
| | % tail ring out |
| L = length(x); | |
| out = zeros(L, 1); | |
| % Create an arbitrary curve of decay time per frequency. | |
| % This example lets higher frequencies decay more rapidly. | |
| maxDecayTime = 20; | % Low-frequency decay time (sec) |
| minDecayTime = 5; | % High-frequency decay time (sec) |
| dd = [1 : −1/(N/2) : 0]’; | % Create a linear curve |
| dd = dd .\hat{ } 5; | % Create a non-linear curve |
| dd = dd * (maxDecayTime − minDecayTime) + minDecayTime; | |
| | % −60 dB decay time |

| % Convert to gains | |
|---|---|
| AttenDB = −60 * hop ./ (dd * FS); | % Attenuation in dB |
| Atten = 10 .\hat{ } (AttenDB/20); | % Linear atten. array |
| Atten(N/2+2:N) = flipud(Atten(2:N/2)); % Include neg. freq. | |
| Atten(N/2+1) = Atten(N/2); | % Nyquist. |

```
% Standard phase increment
omega = 2 * pi * hop * [0:N−1]’ / N;
dryDB = 0;
wetDB = 0;
dry = 10 .\hat{ } (dryDB/20);
wet = 10 .\hat{ } (wetDB/20);
% Initialize arrays
ftWet = zeros(N, 1);
phiWetOld = ftWet;
frame = 0;
s1 = 0;
s2 = L − N;
while s1<s2  % For every hop
    frame = frame + 1;
    grain = x(s1+1:s1+N) .* win;
    ftDry = fft(fftshift(grain));
    ftWet = ftDry + ftWet;
    ftOut = dry * ftDry + wet * ftWet;
    magWet = abs(ftWet) .* Atten;
    if frame < 3
        phiWet = angle(ftDry);
    else
        phiWet = angle(ftWet);
    end
    phiDiff = phiWet − phiWetOld;
    phiWetOld = phiWet;
    % Add some randomness
    phiDiff = phiDiff + 0.4 * 2 * pi * rand(N, 1);
    phiWet = phiWet + phiDiff;
    ftWet = magWet .* exp(i * phiWet);
    y = fftshift(real(ifft(ftOut)));
    grain = y(1:N) .* win;
    out(s1+1:s1+N) = out(s1+1:s1+N) + grain;
    s1 = s1 + hop;
end
maxVal = max(abs(out))
out = out / maxVal;
wavwrite(out, FS, ‘SpectralMagDecay.wav’);
```

One skilled in the art may readily discover various changes that may be made without departing from the true spirit and scope of the invention. For example, the optimal placement and depth of phase randomization, as well as which frequency bins it should be applied to and how often, can be modified. We may consider applying different amounts of phase randomization depending on whether a frequency channel is identified as being in the vicinity of a spectral peak. Also, we may want to apply more phase randomization to higher frequency channels, on the assumption that they don't serve as coherent harmonics.

Given sufficient phase randomization, the impulse response of the Spectral Magnitude Decay algorithm is quite good and resembles decaying noise, with the desired frequency-dependent decay times and no unwanted coloration or metallic effects.

An alternate embodiment of the frequency domain reverberation involves ‘freezing’ each STFT input frame and imposing a frequency-dependent decay on the spectral magnitudes. Time-freezing, or infinite time-scaling, involves extending the magnitude spectrum of an STFT frame indefinitely while propagating the phases based on instantaneous frequency estimates.

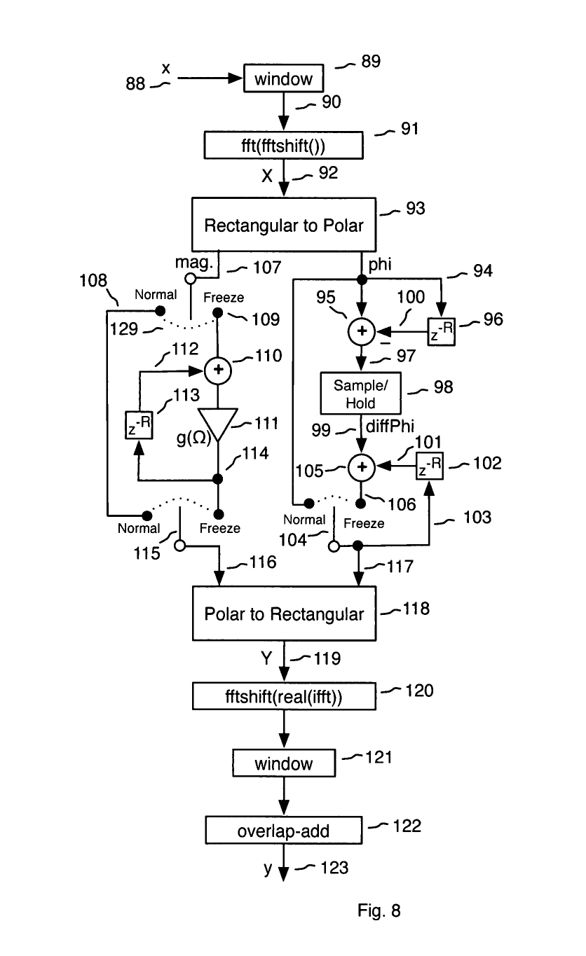

For illustration, a simple time-freeze algorithm (prior art) is shown in FIG. 8. At each hop time (or frame), the input signal x 88 is windowed by a Hanning or similar window 89, resulting in windowed input signal 90. A left-right-swapper-and-fast-Fourier-transform (similar to Matlab functions fft(fftshift( ))) 91 converts the windowed input signal 90 into the frequency domain, resulting in STFT signal 92,

$$X ( {t}_{u} , {Ω}_{k} ) = {\sum }_{n = - ∞}^{∞} h ( n ) x ( {t}_{u} + n ) {e}^{- {jΩ}_{k} n} .$$

### The STFT signal 92 is converted to polar coordinates in Rectangular-to-Polar Converter 93, yielding magnitude 107 and phase 94.

Switches 129, 115 and 104 are thrown from the “Normal” position to the “Freeze” position at the instant the sound is frozen. When these switches are in the “Normal” position, magnitude 107 is sent to magnitude input 116 of Polar-to-Rectangular Converter 118, and phase 94 is sent to phase input 117 of Polar-to-Rectangular Converter 118.

When switches 129 and 115 are in the “Freeze” position, magnitude 107 is sent to Freeze signal 109 and added to delayed magnitude feedback signal 112 in adder 110. The output of adder 110 is scaled by gain g(Ω) in multiplier 111, with

$$g ( {Ω}_{k} ) = {10}^{\frac{3 R}{{T}_{r} ( {Ω}_{k} ) {f}_{s}}} ,$$

resulting in Freeze output signal 114. Freeze output signal 114 is delayed by 1 hop (R samples) in delay 113, resulting in delayed magnitude feedback signal 112. Freeze output signal 114 is also sent to magnitude input 116 of Polar-to-Rectangular Converter 118.

Immediately prior to freezing the sound, we capture the phase deltas (diffPhi 99) for each frequency channel k, ΔØₖ(t_{f})=Øₖ(t_{f})−Øₖ(t_{f-1}), where t_{f} denotes the time of the frame immediately preceding the time freeze. Phase signal 94 is delayed by 1 hop (R samples) in delay 96, and the resulting delayed phase signal 100 is negated and added to phase signal 94 in adder 95. Resulting sum signal 97 is sampled and held at the time of freezing in Sample-and-Hold 98, resulting in difference phase signal diffPhi 99.

When switch 104 is in the “Normal” position, delay 102 receives delay input 103 from phase 94; when switch 104 is in the “Freeze” position, delay 102 receives delay input 103 from sum phase 106. The output of delay 102 is delayed phase 101. Delayed phase 101 is added to difference phase signal diffPhi 99 in adder 105, yielding sum phase 106. When switch 104 is in the “Freeze” position, sum phase 106 is connected to phase input 117.

Magnitude input 116 is combined with phase input 117 and converted to rectangular coordinates in Polar-to-Rectangular Converter 118 to produce Fourier transform signal Y 119. Fourier transform signal Y 119 is converted back to the time domain by an inverse-Fourier-transform-and-left-right swapper (similar to Matlab fftshift(real(ifft))) 120. The resulting time domain signal is windowed by a Hanning or similar window 121 and overlap-added in overlap-adder 122 to produce output y 123. After beginning the Freeze process, the resulting time-frozen signal y 123 has a frequency-dependent decay time.

The method of FIG. 8 simulates the application of a reverb-like decay to a single audio frame. To apply this effect to an ongoing audio signal, one might imagine the following procedure: begin a new time-freeze process in parallel for each successive input frame (applying a frequency-dependent decay to the spectral magnitudes), and sum the time-aligned outputs.

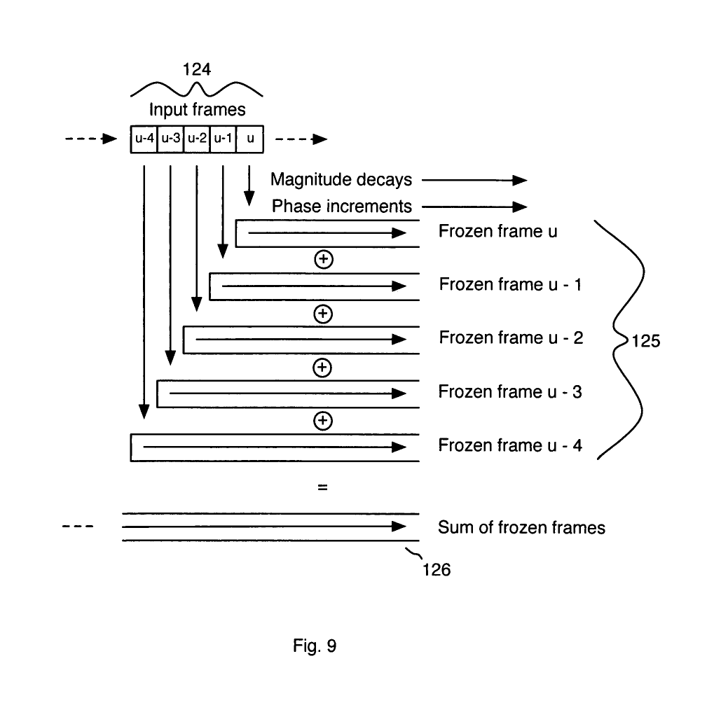

A conceptual overview of this alternate embodiment of the invention is illustrated in FIG. 9. Each of the input frames 124, denoted by “u,” “u-1,” “u-2,” etc., triggers a separate time-freeze process (similar to that shown in FIG. 8). This results in a series of Frozen frames 125, denoted by “Frozen frame u,” “Frozen frame u-1,” “Frozen frame u-2,” etc. All of the Frozen frames 125 are time-aligned and added, resulting in “Sum of frozen frames” 126.

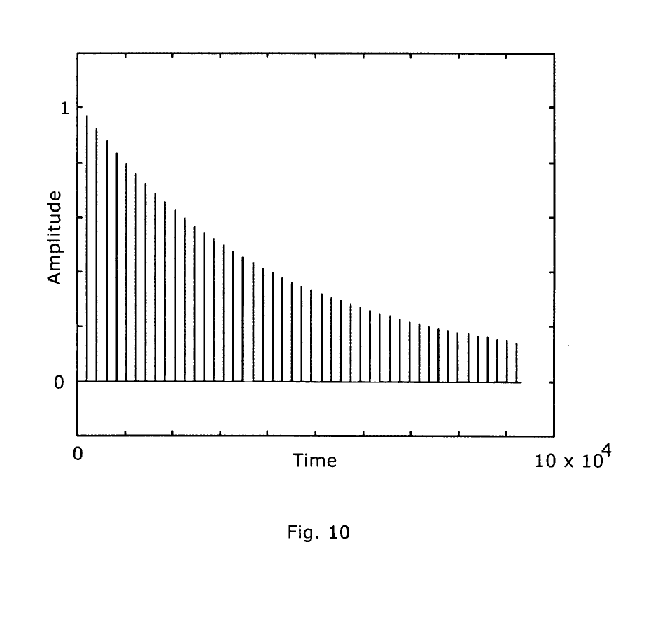

Clearly, such an implementation would result in a data storage and computational explosion, but a simulation of the process yields a very pleasant, reverb-like music response. The impulse response, however, consists of a decaying series of impulses repeated every N samples, as shown in FIG. 10. This problem may be addressed by adding a random phase signal V_{k,u}ψ_{k,u}. The implementation can be made practical by putting a finite limit on the number of frozen frames that are stored.

The current reverb invention, in any of its embodiments, can be implemented digitally by a general purpose computer, a programmable processor (including a digital signal processor) or a custom integrated circuit. If the desired input signal is available only in analog form, it may be converted from analog to digital using an analog-to-digital (A/D) converter; the resulting digital signal is sent to the input of the reverb algorithm. If the signal already exists in digital time-domain form, that signal can be sent directly to the reverb algorithm. If the signal already exists in a suitable digital frequency-domain form, we may be able to bypass the need to perform a Fourier transform and related operations at the input of the reverb algorithm.

If desired, multiple output channels can be generated using multiple inverse Fourier transforms with different phase randomization. The output(s) of the current reverb invention, in any of its embodiments, may be converted from digital to analog (using one or more D/A converters) and then sent to amplifiers, speakers, or other devices. Alternately, the output(s) may be left in digital form for storage or further processing. If additional frequency domain processing is desired, the output(s) can be left in the frequency domain, possibly eliminating the need for inverse Fourier transform(s) and related operations. Thus, the current invention can be especially efficient and advantageous if used in the context of a system which already performs operations in the frequency domain.

While the invention has been described with reference to specific embodiments, it will be understood by those skilled in the art that various changes may be made and equivalents may be substituted for elements thereof without departing from the broader spirit and scope of the invention. In addition, modifications may be made without departing from the essential teachings of the invention. Accordingly, the specifications and drawings are to be regarded in an illustrative rather than a restrictive sense.

What is claimed is:

1. A reverberation device for generating a reverberation signal, the device comprising:
an input means for receiving an audio frequency input signal;
a feedback loop means comprising a frequency domain adder, a frequency domain delay, and an attenuator for attenuating the magnitude of a frequency domain signal as an attenuation function of the audio frequency Ω, to generate an attenuated frequency domain magnitude signal, said attenuation function, expressed in decibels, being proportional to the length of the frequency domain delay and inversely proportional to a desired reverberation time Tᵣ(Ω);
a means for conveying a frequency domain signal from said input means to said feedback loop means;
a phase generator means for generating an artificial phase signal;
a means for combining the attenuated frequency domain magnitude signal with the artificial phase signal to generate a plurality of output signals; and
an output means for providing said output signals.

2. A method for generating a reverberation signal, the method comprising:
conveying an input signal to a frequency domain feedback loop having a frequency domain adder, a frequency domain delay, and a frequency domain attenuator;
attenuating the magnitude of the frequency domain signal as an attenuation function of the audio frequency Ω, to generate an attenuated frequency domain magnitude signal, said attenuation function, expressed in decibels, being proportional to the length of the frequency domain delay and inversely proportional to a desired reverberation time Tᵣ(Ω);
generating an artificial phase signal and combining the artificial phase signal with the attenuated frequency domain magnitude signal to generate a plurality of frequency domain output signals.
